(19) United States
(12) Patent Application Publication
(10) Pub. No.: US 2013/0033275 A1
(43) Pub. Date: Feb. 7, 2013

(54) FUEL PROPERTY DETECTION DEVICE

(71) Applicant: Hiroshi Nakamura, Nishio-city (JP)

(72) Inventor: Hiroshi Nakamura, Nishio-city (JP)

(73) Assignee: DENSO CORPORATION, Kariya-city (JP)

(21) Appl. No.: 13/483,206

(22) Filed: May 30, 2012

(30) Foreign Application Priority Data
Aug. 2, 2011 (JP) 2011-169213

(51) Int. Cl. G01R 27/26; G01N 27/22

(52) U.S. Cl. 324/663

(57) ABSTRACT

A first electrode has a fuel passage. A second electrode defines a predetermined gap with the first electrode in the fuel passage. A third electrode defines a predetermined gap with the second electrode in the fuel passage. The first electrode and the second electrode form a first capacitance therebetween. The second electrode and the third electrode form a second capacitance therebetween. A circuit portion is configured to compute a property of fuel in the fuel passage according to the first capacitance and the second capacitance.

### CROSS REFERENCE TO RELATED APPLICATION

This application is based on reference Japanese Patent Application No. 2011-169213 filed on Aug. 2, 2011, the disclosure of which is incorporated herein by reference.

### TECHNICAL FIELD

The present disclosure relates to a fuel property detection device.

### BACKGROUND

Conventionally, a known fuel property detection device for detecting a property of fuel, such as an alcohol concentration of the fuel, is equipped in a fueling system, which is for supplying fuel to an internal combustion engine. The property of fuel detected with the fuel property detection device is transmitted to an electronic control unit of the internal combustion engine and is utilized for various kinds of controls. The electronic control unit controls a fuel injection quantity and a fuel injection timing of the internal combustion engine according to the detection result of the property of fuel thereby to reduce toxic substance contained in exhaust gas.

A conventional fuel property detection device disclosed in U.S. Pat. No. 7,030,629 B1 includes an external electrode, which defines a fuel passage, and an internal electrode, which is located in the fuel passage, and is configured to detect an alcohol concentration of fuel in the fuel passage according to a capacitance between the external electrode and the internal electrode.

It is noted that, the fuel property detection device disclosed in U.S. Pat. No. 7,030,629 B1 is configured to detect the alcohol concentration according to the capacitance between the pair of the electrodes. Therefore, in the fuel property detection device disclosed in U.S. Pat. No. 7,030,629 B1, as the alcohol concentration changes, the capacitance changes by a small quantity relative to the change in the alcohol concentration. Consequently, the fuel property detection device disclosed in U.S. Pat. No. 7,030,629 B1 has a low resolution in detection of the alcohol concentration.

In consideration of the conventional configuration of U.S. Pat. No. 7,030,629 B1, it is conceivable to elongate both the internal electrode and the external electrode in the longitudinal direction to enlarge opposed areas of the electrodes therebetween, thereby to increase change in the capacitance relative to change in the alcohol concentration. However, in such a configuration with the elongated electrodes, the fuel property detection device may be enlarged in size.

Further, in consideration of the conventional configuration of U.S. Pat. No. 7,030,629 B1, it is further conceivable to reduce the inner diameter of the external electrode or to enlarge the outer diameter of the internal electrode in order to reduce the gap between the electrodes, thereby to enhance change in the capacitance relative to change in the alcohol concentration. However, in such a configuration with the reduced gap, flow resistance caused in the fuel passage may increase to result in increase in operational load of the fuel pump when press-feeding fuel.

### SUMMARY

It is an object of the present disclosure to produce a fuel property detection device configured to detect a property of fuel with high resolution.

According to an aspect of the present disclosure, a fuel property detection device comprises a first electrode having a fuel passage. The fuel property detection device further comprises a second electrode defining a predetermined gap with the first electrode in the fuel passage. The fuel property detection device further comprises a third electrode defining a predetermined gap with the second electrode in the fuel passage. The fuel property detection device further comprises a circuit portion configured to compute a property of fuel in the fuel passage according to a first capacitance, which is formed between the first electrode and the second electrode, and a second capacitance, which is formed between the second electrode and the third electrode.

### BRIEF DESCRIPTION OF THE DRAWINGS

The above and other objects, features and advantages of the present invention will become more apparent from the following detailed description made with reference to the accompanying drawings. In the drawings:

FIG. 1 is a configuration diagram showing a fueling system equipped with a fuel property detection device according to an embodiment of the present disclosure;

FIG. 2 is a sectional view showing the fuel property detection device;

FIG. 3 is a configuration diagram showing an electric circuit of the fuel property detection device;

FIG. 4 is a graph showing relations among an ethanol concentration of fuel between electrodes of the fuel property detection device, a temperature of fuel, and a capacitance of fuel; and

FIG. 5 is a graph showing comparison of a relation, which is between the capacitance and the ethanol concentration of fuel detected with the fuel property detection device of the present disclosure, with a relation, which is between the capacitance and the ethanol concentration of fuel detected with a fuel property detection device, equipped with a pair of electrodes, according to an exemplified embodiment.

### DETAILED DESCRIPTION

As follows, an embodiment of a fuel property detection device will be described with reference to drawings.

### Embodiment

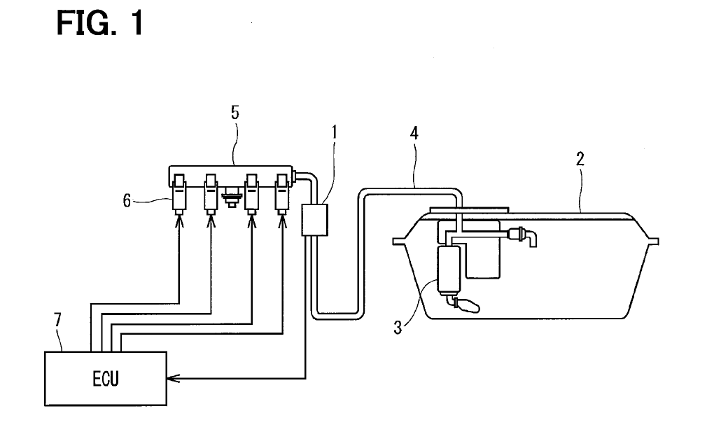

As shown in FIG. 1, a fuel property detection device 10 according to the embodiment of the present disclosure is, for example, employed in a fueling system for an automobile. The fueling system is for supplying fuel to an internal combustion engine (not shown). The fueling system includes a fuel tank 2, a fuel pump 3, a fuel pipe 4, a delivery pipe 5, an injector 6, an electronic control unit (ECU) 7, and the like. The fuel pump 3 draws fuel stored in the fuel tank 2 and press-feeds the drawn fuel through the fuel pipe 4 into the delivery pipe 5. The injector 6 injects the fuel in the delivery pipe 5 into, for example, an intake pipe of the engine or into a cylinder of the engine directly. The ECU 7 electrically controls the operation of the injector 6. The fuel pipe 4 connects the fuel tank 2 with the delivery pipe 5. The fuel property detection device 10 is equipped in the course of the fuel pipe 4.

The fuel tank 2 is supplied with fuel such as ethanol-gasoline mixture, which is produced by mixing gasoline with ethanol. The concentration of ethanol (ethanol concentration) in the ethanol-gasoline mixture is selectable arbitrarily from a range between 0% and 100%. Therefore, the ethanol concentration of fuel in the fuel tank 2 may change when the vehicle is refueled. The fuel property detection device 10 is an ethanol concentration sensor configured to detect the ethanol concentration of fuel flowing through the fuel pipe 4. The fuel property detection device 10 is further configured to generate an electric signal corresponding to the ethanol concentration and to send the electric signal to the ECU 7. The ECU 7 controls a fuel injection quantity, a fuel injection timing, and the like, according to the detected ethanol concentration of fuel immediately before being supplied to the engine. Thus, the ECU 7 controls the engine at an optimal condition. The optimal condition is determined in consideration of, for example, reduction in toxic substance contained in exhaust gas from the engine, as much as possible.

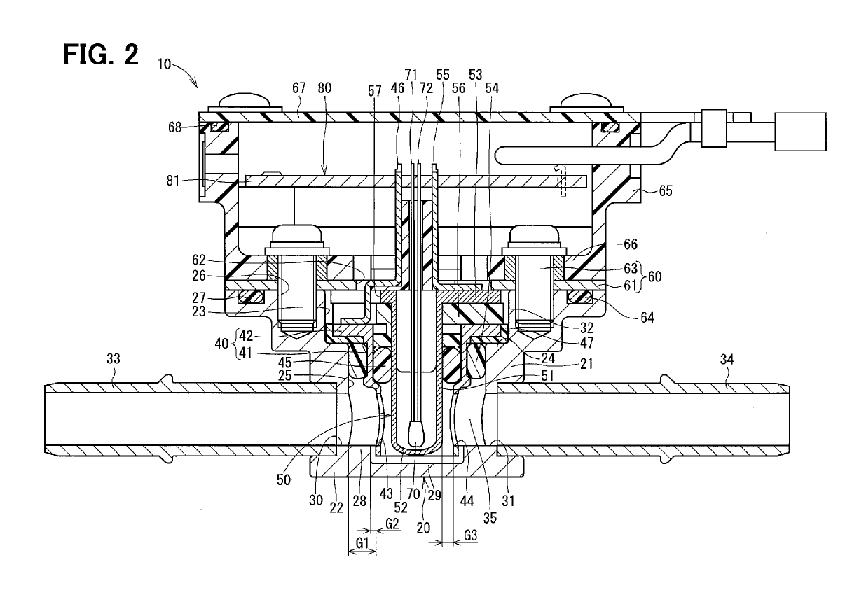

As shown in FIG. 2, the fuel property detection device 10 includes a first electrode 20, a second electrode 40, a third electrode 50, a housing 65, a thermistor 70, a circuit portion 80, and the like. The first electrode 20 is formed of, for example, a metallic material such as stainless steel and is in a closed-end tubular shape. The first electrode 20 includes a tubular portion 21 and a bottom portion 22, which plugs one end of the tubular portion 21. The tubular portion 21 is equivalent to a first tubular portion. The bottom portion 22 is equivalent to a first bottom portion. The first electrode 20 has a first accommodation hole 23 and a second accommodation hole 25. The first accommodation hole 23 opens in the outer wall of the other end of the tubular portion 21 and is defined by a bottom wall 24. The second accommodation hole 25 opens in the bottom wall 24 and is defined by a bottom end. The first accommodation hole 23 is defied by the inner wall of the tubular portion 21 of the first electrode 20. The second accommodation hole 25 is defined by the inner wall of the tubular portion 21 of the first electrode 20 and the inner wall of the bottom portion 22. The inner diameter of the first accommodation hole 23 is greater than the inner diameter of the second accommodation hole 25. The second electrode 40 and the third electrode 50 are located in the first accommodation hole 23 and the second accommodation hole 25. The first electrode 20 functions as a housing of both the second electrode 40 and the third electrode 50. The first electrode 20 and the housing 65 form an outer shell of the fuel property detection device 10.

The tubular portion 21 of the first electrode 20 has an outer wall on the side of the first accommodation hole 23, and the outer wall has multiple screw holes 26 and an O-ring groove 27. The multiple screw holes 26 are circumferentially arranged and are circumferentially distant from each other. The O-ring groove 27 is in an annular shape and surrounds the multiple screw holes 26.

The bottom portion 22 of the first electrode 20 has an inner wall 28 defining a recess 29. The recess 29 is dented oppositely from the tubular portion 21. The end of the second electrode 40 is inserted in the recess 29. The tubular portion 21 of the first electrode 20 has through-holes 30 and 31 at an axial position corresponding to the second accommodation hole 25. The through-holes 30 and 31 extend in the radial direction through the tubular portion 21. The outer wall of the tubular portion 21 of the first electrode 20 has wall portion corresponding to the through-holes 30 and 31, and the wall portion are connected with one ends of tube fittings 33 and 34, respectively. The other ends of the tube fittings 33 and 34 are connected with ends of the fuel pipe 4 (FIG. 1), respectively. Fuel flows through the tube fitting 33 and the through-hole 30, and the fuel flows into the second accommodation hole 25. The fuel further flows through the through-hole 31 and the tube fitting 34, and the fuel flows into the fuel pipe 4. The second accommodation hole 25 functions as a fuel passage 35 for passing fuel therethrough.

The second electrode 40 is formed of, for example, a metallic material such as stainless steel and is in a tubular shape. The second electrode 40 includes a tubular portion 41 and a collar portion 42. The tubular portion 41 is located in the first accommodation hole 23 and the second accommodation hole 25. The collar portion 42 is located in the first accommodation hole 23 and is projected from the tubular portion 41 radially outward. The tubular portion 41 of the second electrode 40 is coaxial with the tubular portion 21 of the first electrode 20. The tubular portion 41 of the second electrode 40 has a tip end on the side of the second accommodation hole 25, and the tip end is inserted in the recess 29 of the bottom portion 22 of the first electrode 20.

The tubular portion 41 of the second electrode 40 has a through-hole 43 and a through-hole 44. The through-hole 43 is located at a circumferential position corresponding to the through-hole 30 and extended through the tubular portion 41. The through-hole 44 is located at a circumferential position corresponding to the through-hole 31 and extended through the tubular portion 41. The through-holes 43 and 44 are configured to pass fuel therethrough.

The outer wall of the tubular portion 41 of the second electrode 40 on the side of the first accommodation hole 23 and the inner wall of the tubular portion 21 of the first electrode 20 define a tubular gap therebetween, and the tubular gap is equipped with a sealing member 54. The sealing member 54 liquid-tightly seals the tubular gap radially between the first electrode 20 and the second electrode 40 to restrict fuel in the fuel passage 35 from leaking into the first accommodation hole 23. The second electrode 40 is electrically coupled with the circuit portion 80 via a terminal 46. The terminal 46 is joined to the collar portion 42. A collar portion 53 of the third electrode 50 has a slit 57. A holding plate 61 has a through-hole 62. The terminal 46 extends through the slit 57 and the through-hole 62 to the outside of the first electrode 20.

An annular first insulating member 47 is equipped between the second electrode 40 and the first electrode 20. The first insulating member 47 occupies a gap defined between the collar portion 42 of the second electrode 40 and the bottom wall 24 in the axial direction. The first insulating member 47 further occupies a gap defined between an inner wall 32 defining the first accommodation hole 23 and the collar portion 42 of the second electrode 40 in the radial direction. The first insulating member 47 electrically insulates the second electrode 40 from the first electrode 20. The tubular portion 41 of the second electrode 40 is located in the fuel passage 35, and the tubular portion 41 defines a predetermined gap G1 with the tubular portion 21 of the first electrode 20. The tip end of the tubular portion 41 of the second electrode 40 on the side of the second accommodation hole 25 is located in the recess 29 of the bottom portion 22 of the first electrode 20, and the tip end defines a predetermined gap G2 with the inner wall of the recess 29. The gap G2 is set to be smaller than the gap G1. When fuel flows through the fuel passage 35, the gap G1 and the gap G2 are filled with fuel. In the present state, the first electrode 20 and the second electrode 40 are distant from each other via the fuel as a dielectric medium to form a first capacitor.

The third electrode 50 is formed of, for example, a metallic material such as stainless steel and is in a closed-end tubular shape. The third electrode 50 includes a tubular portion 51, a bottom portion 52, and the collar portion 53. The tubular portion 51 is equivalent to a second tubular portion and is located in both the first accommodation hole 23 and the tubular portion 41 of the second electrode 40. The bottom portion 52 is equivalent to a second bottom portion. The bottom portion 52 plugs the end of the tubular portion 51 on the side of the bottom portion 22. The collar portion 53 is located in the first accommodation hole 23 and is projected from the tubular portion 51 radially outward. The tubular portion 51 of the third electrode 50 is coaxial with the tubular portion 41 of the second electrode 40. The third electrode 50 is inserted into the first electrode 20 in the same direction as the direction in which the second electrode 40 is inserted into the first electrode 20. The bottom portion 52 isolates the inner space of the tubular portion 51 of the third electrode 50 from the fuel passage 35. The outer wall of the tubular portion 51 of the third electrode 50 and the inner wall of the tubular portion 41 of the second electrode 40 define a tubular gap therebetween, and the tubular gap is equipped with a sealing member 45. The sealing member 45 liquid-tightly seals the tubular gap radially between the second electrode 40 and the third electrode 50 to restrict fuel in the fuel passage 35 from leaking into the first accommodation hole 23.

The third electrode 50 is electrically coupled with the circuit portion 80 via a terminal 55 joined to the collar portion 53. The terminal 55 extends through the through-hole 62 of the holding plate 61 to the outside of the first electrode 20.

An annular second insulating member 56 is equipped between the third electrode 50 and the second electrode 40. The second insulating member 56 occupies a gap between the collar portion 53 of the third electrode 50 and the collar portion 42 of the second electrode 40 in the axial direction. The second insulating member 56 further occupies a gap between the tubular portion 51 of the third electrode 50 and the tubular portion 41 of the second electrode 40 in the radial direction. The second insulating member 56 electrically insulates the third electrode 50 from the second electrode 40.

The tubular portion 51 of the third electrode 50 is located in the fuel passage 35, and the tubular portion 51 defines a predetermined gap G3 with the tubular portion 41 of the second electrode 40. When fuel flows through the fuel passage 35, the gap G3 is filled with fuel. In the present state, the second electrode 40 and the third electrode 50 are distant from each other via the fuel as a dielectric medium to form a second capacitor.

The second electrode 40 and the third electrode 50 are affixed to the first electrode 20 with a fastener 60. The fastener 60 includes the holding plate 61 and screws 63. The holding plate 61 is formed of, for example, a metallic material such as stainless steel and is in a disc-shape. The holding plate 61 is equivalent to an affixing member. The holding plate 61 is in contact with both the outer wall of the tubular portion 21 of the first electrode 20 on the side of the first accommodation hole 23 and the outer wall of the collar portion 53 of the third electrode 50 on the opposite side from the tubular portion 51. The holding plate 61 functions as a conductor configured to couple the first electrode 20 electrically with the third electrode 50.

Screws 63 are inserted into the screw holes 26 of the first electrode 20 respectively to affix the holding plate 61 with the first electrode 20. The inner diameter of the through-hole 62 of the holding plate 61 is smaller than the outer diameter of the collar portion 53 of the third electrode 50. The present configuration prohibits the third electrode 50 from moving out of the first accommodation hole 23 and the second accommodation hole 25. An O-ring 64 is located in the O-ring groove 27 liquid-tightly to seal the gap between the holding plate 61 and the first electrode 20. The third electrode 50, the first insulating member 47, the second electrode 40, and the second insulating member 56 are interposed between the holding plate 61 and the bottom wall 24 of the first accommodation hole and thereby affixed to the first electrode 20. The fastener 60 electrically conducts the first electrode 20 with the third electrode 50 and affixes the third electrode 50 and the second electrode 40 to the first electrode 20.

The housing 65 is formed of, for example, a resin material and is in a bottomed tubular shape. A bottom portion 66 of the housing 65 and the holding plate 61 are affixed to the first electrode 20 via the screws 63. The housing 65 has an opening closed with a cover 67. The housing 65 and the cover 67 define a gap therebetween, and the gap is sealed liquid-tightly with an O-ring 68.

The thermistor 70 functions as a temperature detection element (temperature sensor) configured to change its electrical resistance according to variation in temperature. The inner space of the third electrode 50 is charged with a heat conducting material such as heat dissipation grease. The thermistor 70 is located in the heat conducting material within the third electrode 50 and is electrically coupled with the circuit portion 80 via terminals 71 and 72. Fuel in the fuel passage 35 emits heat, and the heat of fuel is conducted through the third electrode 50 and the heat conducting material within the third electrode 50 to the thermistor 70. In the present configuration, the temperature of the thermistor 70 is substantially the same as the temperature of fuel in the fuel passage 35: The thermistor 70 detects the temperature of fuel in the fuel passage 35 indirectly.

The circuit portion 80 includes a circuit board 81 and a concentration acquisition unit. The circuit board 81 is affixed in the housing 65. The concentration acquisition unit is configured with multiple electronic components equipped on the circuit board 81.

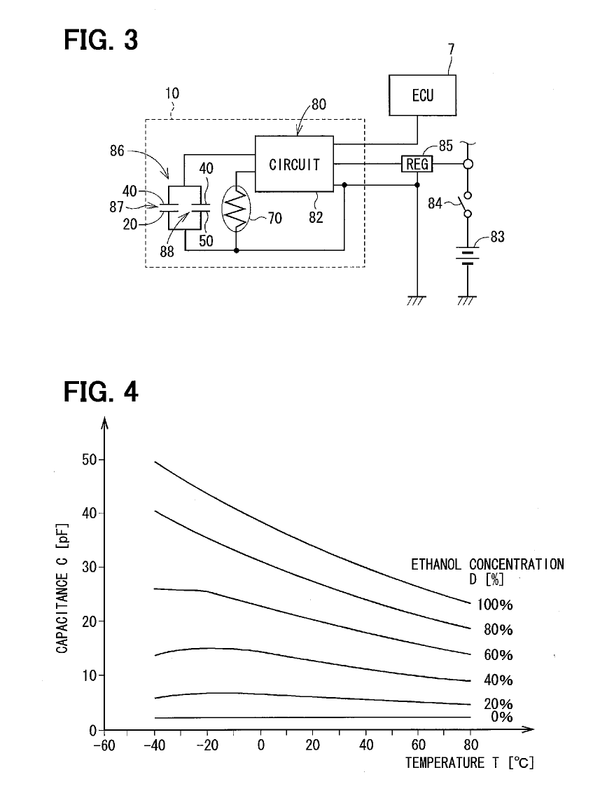

As shown in FIG. 3, the circuit portion 80 is supplied with an electric power from a battery 83 through an ignition switch device 84. The battery 83 functions as an electric power source. The electric circuit between the circuit portion 80 and the battery 83 is equipped with a constant-voltage regulator 85 in order to stabilize the voltage applied to the circuit portion 80. The circuit portion 80 is connected with two electric power supply lines and an electric signal transmission line for transmitting the electric signal to the ECU 7.

A concentration detecting unit 86 includes a first capacitor 87 and a second capacitor 88. The first capacitor 87 is configured with the first electrode 20 and the second electrode 40. The second capacitor 88 is configured with the second electrode 40 and the third electrode 50. The first capacitor 87 and the second capacitor 88 are connected in parallel with a concentration acquisition unit 82. The second electrode 40 is coupled with a positive-terminal side of the battery 83. The first electrode 20 and the third electrode 50 are coupled with a negative-terminal side of the battery 83. The first capacitor 87 has a first capacitance, and the second capacitor 88 has a second capacitance. The total capacitance of the concentration detecting unit 86 is equal to the sum of the first capacitance and the second capacitance. The total capacitance of the concentration detecting unit 86 is referred to as a combined capacitance.

Under a specific temperature, the combined capacitance and the ethanol concentration of fuel between the electrodes show a correlation. In addition, under a specific ethanol concentration, the combined capacitance and the temperature of fuel between the electrodes show a correlation. By utilizing these characteristics, the concentration acquisition unit 82 detects the ethanol concentration of fuel according to the combined capacitance and the temperature of fuel.

Specifically, the concentration acquisition unit 82 manipulates a switch device periodically to switch over a charge state and a discharge state. In the charge state, the concentration detecting unit 86 is applied with a. direct-current voltage, and the first capacitor 87 and the second capacitor 88 are charged with an electric charge. In the discharge state, application of the direct-current voltage is stopped, and the electric charge is discharged from the first capacitor 87 and the second capacitor 88. The concentration acquisition unit 82 further detects the voltage potential difference (in-discharge voltage potential difference) between, for example, the terminal 46 and the terminal 55 at the time of the electric discharge. A property of the in-discharge voltage potential difference, such as the maximum value of the in-discharge voltage potential difference, has a proportional relation with the combined capacitance. The concentration acquisition unit 82 retrieves the combined capacitance according to the in-discharge voltage potential difference with reference to a data map, which defines the relation between the in-discharge voltage potential difference and the combined capacitance. Alternatively, for example, the concentration acquisition unit 82 calculates the combined capacitance according to the in-discharge voltage potential difference by substituting these values into a computing equation. The data map, the computing equation, and the like, which are used by the concentration acquisition unit 82, are beforehand stored in a storage medium (not shown) such as a ROM included in the concentration acquisition unit 82. Similar rule is applied to the below-described data map, the computing equation, and the like.

The concentration acquisition unit 82 assigns the voltage, which is applied between the terminal 71 and the terminal 72, and the electric current, which is flowing through the thermistor 70 at this time, to the Ohm's law thereby to calculate the resistance of the thermistor 70. The resistance of the thermistor 70 changes according to variation in temperature of fuel. The concentration acquisition unit 82 retrieves the temperature of fuel according to the resistance of the thermistor 70 with reference to a data map, which defines the relation between the temperature of fuel and the resistance of the thermistor 70. Alternatively, for example, the concentration acquisition unit 82 calculates the temperature of fuel according to the resistance of the thermistor 70 by substituting these values into a computing equation.

The concentration acquisition unit 82 retrieves the ethanol concentration of fuel according to the combined capacitance of the concentration detecting unit 86 and the temperature of fuel with reference to a data map, which defines the relation among the ethanol concentration of fuel, the combined capacitance of the concentration detecting unit 86, and the temperature of fuel. Alternatively, for example, the concentration acquisition unit 82 calculates the ethanol concentration of fuel according to the combined capacitance of the concentration detecting unit 86 and the temperature of fuel by substituting these values into a computing equation. The relation is represented by, for example, the graph shown in FIG. 4. The graph of FIG. 4 is defined in the two-dimensional coordinates including the vertical axis, which represents the combined capacitance C pF, and the horizontal axis, which represents the temperature of fuel T° C. The diagram of FIG. 4 represents multiple lines each formed by connecting the points where the ethanol concentration of fuel D % is the same. FIG. 4 shows the ethanol concentration D from 0% to 100% at the interval of 20%. It is noted that, the interval of 20% is determined for convenience, and the ethanol concentration D is actually defined further finely.

As described above, the fuel property detection device 10 of the present embodiment includes the three electrodes 20, 40, 50, and the circuit portion 80. The first electrode 20 is configured with the housing defining the fuel passage 35. The second electrode 40 defines the predetermined gaps G1 and G2 with the first electrode 20 in the fuel passage 35. The third electrode 50 defines the predetermined gap G3 with the second electrode 40 in the fuel passage 35. The circuit portion 80 acquires the combined capacitance being the sum of the first capacitance, which is formed between the first electrode 20 and the second electrode 40, and the second capacitance, which is formed between the second electrode 40 and the third electrode 50. The circuit portion 80 further calculates or retrieves the ethanol concentration of fuel in the fuel passage 35 according to the acquired combined capacitance by utilizing the computing equation or with reference to the data map.

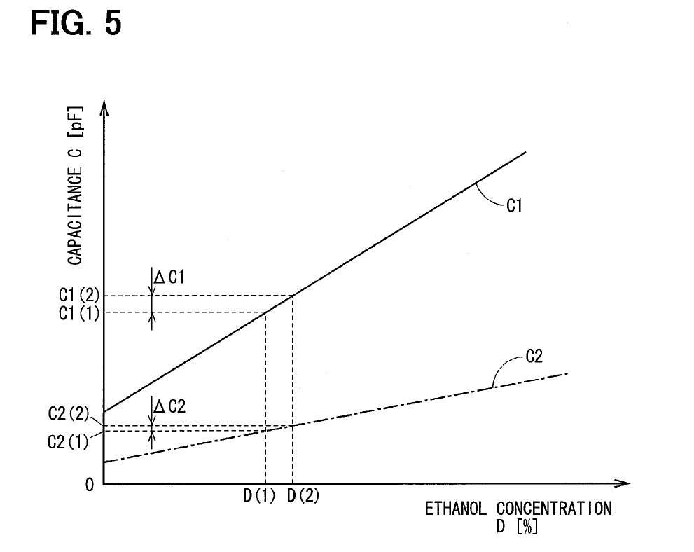

In the present configuration, the combined capacitance acquired by the circuit portion 80 changes largely relative to variation in the ethanol concentration of fuel. The present subject will be described with reference to FIG. 5. In FIG. 5, the solid line C1 represents the relation between the combined capacitance C1 and the ethanol concentration D detected with the fuel property detection device 10 of the present embodiment, under a constant temperature. The dashed dotted line C2 represents the relation between the capacitance C2 and the ethanol concentration D detected with a fuel property detection device of an exemplified embodiment, under the constant temperature. Thee fuel property detection device of the exemplified embodiment includes, only the combination of the second electrode 40 and the third electrodes 50. As shown in FIG. 5, the slope of the solid line C1 is steeper than the slope of the solid line C2. In FIG. 5, when the ethanol concentration D of fuel changes from the predetermined value D(1) to the predetermined value D(2), the combined capacitance C1 according to the present embodiment changes by the variation ΔC1 (=C1(2)−C1(1)), and the capacitance C2 according to the exemplified embodiment changes by the variation ΔC2 (=C2(2)−C2(1)). As clearly shown in FIG. 5, the variation ΔC1 is greater than the variation ΔC2, because of the difference between the slopes. Therefore, the fuel property detection device 10 according to the present embodiment is configured to detect the ethanol concentration D of fuel with high resolution.

In addition, according to the present embodiment, the holding plate 61 is equipped to conduct electrically the first electrode 20 with the third electrode 50. In the present configuration, the first capacitor 87, which is configured with the first electrode 20 and the second electrode 40, and the second capacitor 88, which is configured with the second electrode 40 and the third electrode 50, are connected in parallel to each other in the electric circuit. Thus, the circuit portion 80 acquires the combined capacitance being the sum of the first capacitance and the second capacitance. Therefore, the variation in the combined capacitance acquired with the circuit portion 80 becomes large relative to the change in the ethanol concentration of fuel. Thus, the ethanol concentration of fuel is detectable with high resolution.

According to the present embodiment, the holding plate 61 is configured with the affixing member, which affixes the third electrode 50 to the first electrode 20. Therefore, it is not necessary to equip an additional component for electrically conducting the first electrode 20 with the third electrode 50. Thus, the number of components can be reduced.

According to the present embodiment, the electrodes 20, 40, 50 are substantially coaxial with each other. In the present configuration, the second electrode 40 and the third electrode 50 can be inserted into the first electrode 20 in the same direction. Therefore, the electrodes can be assembled easily.

According to the present embodiment, the bottom portion 22 of the first electrode 20 has the recess 29 dented inward. The end of the second electrode 40 on the side, of the bottom portion 22 is inserted into the recess 29. In the present configuration, the first capacitance can be easily controlled by modifying the inner diameter of the recess 29.

In addition, the gap G2 between the inner wall defining the recess 29 and the outer wall of the second electrode 40 is distant from (i.e., shifted relative to) the fuel passage 35 defined in the tubular portion 21 of the first electrode 20. Therefore, even when the gap G2 between the inner wall defining the recess 29 and the outer wall of the second electrode 40 is set at a narrow clearance, the flow resistance in the fuel passage 35 does not increase. Thus, the present configuration enables to set the gap G2 at a narrow clearance thereby to enlarge the variation in the capacitance relative to the change in the ethanol concentration of fuel.

According to the present embodiment, the second electrode 40 is coupled with the positive-terminal side of the battery 83, which is for supplying electric power to the circuit portion 80. In addition, the first electrode 20 and the third electrode 50 are coupled with the negative-terminal side of the battery 83. With the present configuration, even when the first electrode 20, which forms the outer shell of the fuel property detection device 10, is in contact with another component such as a vehicle body, error does not arise in the detection signal. Therefore, occurrence of detection error can be avoided.

In addition, according to the present embodiment, the thermistor 70 is equipped to detect the temperature of fuel in the fuel passage 35. The circuit portion 80 calculates the ethanol concentration of fuel flowing through the fuel passage 35 according to the temperature of fuel detected with the thermistor 70, in addition to the first capacitance and the second capacitance. In this way, the ethanol concentration of fuel can be calculated accurately according to the temperature of fuel.

In addition, according to the present embodiment, the third electrode 50 is in the bottomed tubular shape to have the inner space isolated from the fuel passage 35. The thermistor 70 is located in the third electrode 50. In this way, the thermistor 70 can be isolated from fuel in the fuel passage 35.

### Other Embodiment

According to another embodiment of the present disclosure, the fuel property detection device may be employed to detect the alcohol concentration of alcohol blended gasoline, which is mixture of gasoline with alcohol other than ethanol. The fuel property detection device may be employed to detect a property of fuel other than the alcohol concentration. In short, the fuel property detection device may be employed for detecting various properties of fuel according to the capacitances of the three electrodes.

The property of fuel may be calculated from a relation represented by a computing equation and/or the like.

The voltage applied to the electrodes is not limited to a direct-current voltage and may be an alternating voltage.

The temperature sensor is not limited to the thermistor and may be another temperature sensor having a different configuration.

The circuit portion may be configured to detect the ethanol concentration according to only the first capacitance and the second capacitance. The circuit portion may be configured to detect the ethanol concentration according to the outdoor temperature, the temperature of fuel in the fuel tank, and/or the like, in addition to the first capacitance and the second capacitance. In this case, the fuel property detection device may not include the temperature sensor such as a thermistor.

The first electrode, the second electrode, and the third electrode may be in a shape other than the tubular shape. The first electrode, the second electrode, and the third electrode may not be coaxial with each other. The second electrode and/or the third electrode may be, for example, in a stick shape or in a plate shape. The first electrode need not be in a bottomed tubular shape and may be in a hollow shape having a fuel passage therein.

The end of the second electrode need not be located in the recess of the first electrode. The first electrode need not have the recess.

The first electrode and the third electrode may be electrically conducted via a component other than the affixing member affixing the second electrode and the third electrode to the first electrode. It suffices that the conductor electrically conducts the first electrode with the third electrode, and the conductor may not be in a disc-shape.

The third electrode and the holding plate may be one piece. For example, the collar portion extended from the third electrode radially outward may be affixed to the first electrode with a screw or the like.

Separately from the terminal, which conducts the third electrode with the circuit board of the circuit portion, an additional terminal may be equipped to conduct the first electrode with the circuit board of the circuit portion. In this configuration, an additional conductor may be equipped to the circuit board of the circuit portion to conduct the first electrode with the third electrode.

In place of the holding plate, another component may be equipped to affix both the second electrode and the third electrode to the first electrode. For example, the holding plate may be omitted, and both the second electrode and the third electrode may be interposed between the bottom portion of the housing and the first electrode.

Both the second electrode and the third electrode may be affixed to a component, such as the housing, other than the first electrode.

The fuel property detection device is not limited to be equipped to the intermediate portion of the fuel pipe, which connects the fuel tank with the delivery pipe. The fuel property detection device may be equipped directly in the fuel tank or may be equipped directly to the delivery pipe.

Summarizing the present disclosure, the above-described fuel property detection device includes the first electrode, the second electrode, the third electrode, and the circuit portion. The first electrode has the fuel passage. The second electrode is located in the fuel passage. The second electrode defines the predetermined gap with the first electrode. The third electrode is located in the fuel passage. The third electrode defines the predetermined gap with the second electrode. The circuit portion is configured to compute the property of fuel in the fuel passage according to the first capacitance, which is formed between the first electrode and the second electrode, and the second capacitance, which is formed between the second electrode and the third electrode. The capacitance between the electrodes and the property of fuel have a correlation therebetween. As the property of fuel changes, the capacitance also changes with the change in the property of fuel. As the property of fuel changes, the combined capacitance, which is the sum of the capacitance values of the two pairs of the electrodes, changes, and a single capacitance value between one of the two pairs of the electrodes also changes. In the present configuration, when the property of fuel changes by a predetermined quantity, change in the combined capacitance is greater than change in the single capacitance value. Therefore, as the property of fuel changes, the combined capacitance acquired with the circuit portion changes further greatly compared with the single capacitance value between one pair of electrodes acquired with the circuit portion. Therefore, the present configuration enables detection of the property of fuel with high resolution.

The fuel property detection device may be further equipped with the conductor to electrically conduct the first electrode with the third electrode. In the present configuration, the first capacitor, which is formed between the first electrode and the second electrode, and the second capacitor, which is formed between the second electrode and the third electrode, may be connected in parallel to each other in the electric circuit. With the present configuration, the circuit portion is enabled to acquire the combined capacitance being the sum of the first capacitance and the second capacitance. Therefore, change in the capacitance relative to change in the property of fuel is enhanced. Thus, the present configuration enables detection of the property of fuel with high resolution.

The conductor may include the affixing member affixing the third electrode with the first electrode. With the present configuration, it is not necessary to equip an additional component for electrically conducting the first electrode with the third electrode. Thus, the number of components can be reduced.

The first electrode may be in the bottomed tubular shape and may include the first tubular portion and the first bottom portion. In this case, the first bottom portion may plug one end of the first tubular portion. The second electrode may be in the tubular shape and may be located in the first tubular portion. In this case, the third electrode may be in the tubular shape and may be located in the second electrode. In this case, the first electrode, the second electrode, and the third electrode may have axes respectively, and the axes may be substantially in parallel with each other. In the present configuration, the second electrode and the third electrode can be inserted into the first electrode in the same direction. Therefore, the electrodes can be assembled easily.

The first bottom portion may have the inner wall defining the recess dented in the opposite direction from the first tubular portion. In this case, the end of the second electrode on the side of the first bottom portion of the first electrode may be located inside the recess. In the present configuration, the, first capacitance can be easily adjusted by modifying the inner diameter of the recess.

The second electrode may be connected with the positive-terminal side (or the positive-terminal) of the electric power source, which is configured to supply electric power to the circuit portion. In this case, the first electrode and the third electrode may be connected with the negative-terminal side (or the negative-terminal) of the electric power source. With the present configuration, even when the first electrode, which forms the outer shell of the fuel property detection device, is in contact with another component such as a vehicle body, error does not arise in the detection signal. Therefore, occurrence of detection error can be avoided.

The fuel property detection device may be further equipped with the temperature sensor configured to detect the temperature of fuel in the fuel passage.

In this case, the circuit portion may be configured to calculate the property of fuel in the fuel passage according to the temperature of fuel detected with the temperature sensor, in addition to the first capacitance and the second capacitance. In this way, the property of fuel can be calculated accurately according to the temperature of fuel. The third electrode may be in the bottomed tubular shape and may include the second tubular portion and the second bottom portion. In this case, the second bottom portion may plug one end of the second tubular portion on the side of the fuel passage. In the present configuration, the temperature sensor is located inside the second tubular portion. In this way, the temperature sensor can be isolated from fuel in the fuel passage.

While the present disclosure has been described with reference to preferred embodiments thereof, it is to be understood that the disclosure is not limited to the preferred embodiments and constructions. The present disclosure is intended to cover various modification and equivalent arrangements. In addition, while the various combinations and configurations, which are preferred, other combinations and configurations, including more, less or only a single element, are also within the spirit and scope of the present disclosure.

What is claimed is:

1. A fuel property detection device comprising:
a first electrode having a fuel passage;
a second electrode defining a predetermined gap with the first electrode in the fuel passage;
a third electrode defining a predetermined gap with the second electrode in the fuel passage; and
a circuit portion configured to compute a property of fuel in the fuel passage according to a first capacitance, which is formed between the first electrode and the second electrode, and a second capacitance, which is formed between the second electrode and the third electrode.

2. The fuel property detection device according to claim 1, further comprising:
a conductor electrically conducting the first electrode with the third electrode.

3. The fuel property detection device according to claim 2, wherein the conductor includes an affixing member affixing the third electrode with the first electrode.

4. The fuel property detection device according to claim 1, wherein
the first electrode is in a bottomed tubular shape and includes a first tubular portion and a first bottom portion, the first bottom portion plugging one end of the first tubular portion,
the second electrode is in a tubular shape and is located in the first tubular portion,
the third electrode is in a tubular shape and is located in the second electrode, and
the first electrode, the second electrode, and the third electrode have axes respectively, the axes being substantially in parallel with each other.

5. The fuel property detection device according to claim 4, wherein
the first bottom portion of the first electrode has an inner wall defining a recess dented away from the first tubular portion, and
the second electrode has an end on a side of the first bottom portion, the end of the second electrode being located in the recess.

6. The fuel property detection device according to claim 1, wherein
the second electrode is connected with a positive-terminal side of an electric power source, which is configured to supply electric power to the circuit portion, and
the first electrode and the third electrode are connected with a negative-terminal side of the electric power source.

7. The fuel property detection device according to claim 1, further comprising:
a temperature sensor configured to detect a temperature of fuel in the fuel passage, wherein
the circuit portion is configured to compute the property of fuel in the fuel passage according to the first capacitance, the second capacitance, and the temperature of fuel.

8. The fuel property detection device according to claim 7, wherein
the third electrode is in a bottomed tubular shape and includes a second tubular portion and a second bottom portion, the second bottom portion plugging one end of the second tubular portion to isolate an inner space of the second tubular portion from the fuel passage, and
the temperature sensor is located in the second tubular portion of the third electrode.
